(19) United States
(12) Patent Application Publication
(10) Pub. No.: US 2024/0356608 A1
(43) Pub. Date: Oct. 24, 2024

(54) METHOD AND APPARATUS FOR EFFICIENT CHANNEL STATE INFORMATION REPRESENTING

(71) Applicant: MediaTek Singapore Pte. Ltd., Singapore (SG)

(72) Inventors: Yahia Ahmed Mahmoud Mahmoud SHABARA, San Jose, CA (US); Gyu Bum KYUNG, San Jose, CA (US)

(21) Appl. No.: 18/684,803

(22) PCT Filed: Jan. 12, 2023
(86) PCT No.: PCT/US2023/060552

§ 371 Date: Feb. 19, 2024

Related U.S. Application Data
(60) Provisional application No. 63/303,570, filed on Jan. 27, 2022.

(51) Int. Cl. H04B 7/06; H04W 24/02; H04W 28/06

(52) U.S. Cl. CPC H04B 7/0626; H04W 24/02; H04W 28/06

(57) ABSTRACT

First processing circuitry of a first apparatus for compressing channel state information (CSI) classifies a CSI element into one of multiple classes of CSI elements. Each class is associated with a different one of multiple encoders. The first processing circuitry compresses the CSI element based on one of the multiple encoders associated with the one of the multiple classes of CSI elements, and sends, to a second apparatus, the compressed CSI element and a class index of the one of the multiple classes of CSI elements. Second processing circuitry of the second apparatus for decompressing CSI receives the compressed CSI element and the class index. Each class of CSI elements is associated with a different one of multiple decoders. The second processing circuitry determines one of the multiple decoders based on the class index, and decompresses the CSI element based on the determined decoder to obtain a decompressed CSI element.

### INCORPORATION BY REFERENCE

This present disclosure claims the benefit of U.S. Provisional Application No. 63/303,570, filed on Jan. 27, 2022, which is incorporated herein by reference in its entirety.

### TECHNICAL FIELD

The present disclosure relates to wireless communications, and specifically to a procedure for classifying and compressing channel state information between a transmitter and a receiver.

### BACKGROUND

In wireless communications, channel state information (CSI) can estimate channel properties of a communication link between a transmitter and a receiver. In related arts, the receiver can estimate the CSI of the communication link and feedback the raw CSI to a transmitter. This procedure can consume a great deal of communication resources and place a tremendous strain on a wireless network using modern multiple-input and multiple-output (MIMO) technology.

### SUMMARY

Aspects of the disclosure provide a method of compressing channel state information (CSI). Under the method, at a first device, a CSI element is classified into one of multiple classes of CSI elements. Each class of CSI elements is associated with a different one of multiple encoders. At the first device, the CSI element is compressed based on one of the multiple encoders that is associated with the one of the multiple classes of CSI elements. The compressed CSI element and a class index of the one of the multiple classes of CSI elements are sent to a second device.

In an embodiment, the first device, a plurality of CSI elements is clustered into the multiple classes of CSI elements, and a pair of encoder-decoder algorithm is trained for each class of CSI elements.

In an embodiment, at the first device, the CSI element is compressed based on one of the multiple pairs of encoder-decoder algorithms that is associated with the one of the multiple classes of CSI elements.

In an embodiment, at the first device, the plurality of CSI elements is clustered into the multiple classes of CSI elements based on a K-mean clustering algorithm.

In an embodiment, a number of the multiple classes of CSI elements is predetermined.

Aspects of the disclosure provide an apparatus for compressing CSI. The apparatus includes processing circuitry that classifies a CSI element into one of multiple classes of CSI elements. Each class of CSI elements is associated with a different one of multiple encoders. The processing circuitry compresses the CSI element based on one of the multiple encoders that is associated with the one of the multiple classes of CSI elements. The processing circuitry sends, to a second apparatus, the compressed CSI element and a class index of the one of the multiple classes of CSI elements.

In an embodiment, the processing circuitry clusters a plurality of CSI elements into the multiple classes of CSI elements, and trains a pair of encoder-decoder algorithm for each class of CSI elements.

In an embodiment, the processing circuitry compresses the CSI element based on one of the multiple pairs of encoder-decoder algorithms that is associated with the one of the multiple classes of CSI elements.

In an embodiment, the processing circuitry clusters the plurality of CSI elements into the multiple classes of CSI elements based on a K-mean clustering algorithm.

In an embodiment, a number of the multiple classes of CSI elements is predetermined.

Aspects of the disclosure provide a method of decompressing CSI. Under the method, a compressed CSI element and a class index of one of multiple classes of CSI elements are received. Each class of CSI elements is associated with a different one of multiple decoders. One of the multiple decoders is determined based on the class index. The CSI element is decompressed based on the one of the multiple decoders to obtain a decompressed CSI element.

In an embodiment, each class of CSI elements is associated with a pair of encoder-decoder algorithm.

In an embodiment, at the apparatus, the CSI element is compressed based on one of the multiple pairs of encoder-decoder algorithms that is associated with the one of the multiple classes of CSI elements.

In an embodiment, the multiple classes of CSI elements are clustered from a plurality of CSI elements based on a K-mean clustering algorithm.

In an embodiment, a number of multiple classes of CSI elements is predetermined.

Aspects of the disclosure provide an apparatus for decompressing CSI. The apparatus includes processing circuitry that receives a compressed CSI element and a class index of one of multiple classes of CSI elements. Each class of CSI elements being associated with a different one of multiple decoders. The processing circuitry determines one of the multiple decoders based on the class index, and decompresses the CSI element based on the one of the multiple decoders to obtain a decompressed CSI element.

In an embodiment, each class of CSI elements is associated with a pair of encoder-decoder algorithm.

In an embodiment, the processing circuitry decompresses the CSI element based on one of the multiple pairs of encoder-decoder algorithms that is associated with the one of the multiple classes of CSI elements.

In an embodiment, the multiple classes of CSI elements are clustered from a plurality of CSI elements based on a K-mean clustering algorithm.

In an embodiment, a number of multiple classes of CSI elements is predetermined.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows an exemplary procedure of CSI reporting according to embodiments of the disclosure;

FIG. 2 shows another exemplary procedure of CSI reporting according to embodiments of the disclosure;

FIG. 3 shows an exemplary procedure of classifying a CSI element according to embodiments of the disclosure;

FIG. 4A-4C show another exemplary procedure of CSI reporting according to embodiments of the disclosure;

FIG. 5 shows an exemplary apparatus according to embodiments of the disclosure;

FIG. 6 shows an exemplary computer system according to embodiments of the disclosure;

FIG. 7 shows an exemplary process for compressing CSI according to embodiments of the disclosure; and

FIG. 8 shows an exemplary process for decompressing CSI according to embodiments of the disclosure.

### DETAILED DESCRIPTION OF EMBODIMENTS

The detailed description set forth below in connection with the appended drawings is intended as a description of various configurations and is not intended to represent the only configurations in which the concepts described herein may be practiced. The detailed description includes specific details for the purpose of providing an understanding of various concepts. However, these concepts may be practiced without these specific details.

Several aspects of telecommunication systems will now be presented with reference to various apparatuses and methods. These apparatuses and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

In wireless communications, channel state information (CSI) can estimate channel properties of a communication link between a transmitter and a receiver. For example, CSI can describe how a signal propagates from the transmitter to the receiver, and represent a combined effect of phenomena such as scattering, fading, power loss with distance, and the like. Thus, CSI can also be referred to as channel estimation. CSI can make it feasible to adapt the transmission between the transmitter and the receiver to current channel conditions, and thus is a critical piece of information that needs to be shared between the transmitter and the receiver to allow high-quality signal reception.

In an example, the transmitter and the receiver (or transceivers) can rely on CSI to compute their transmit precoding and receive combining matrices, among other important parameters. Without CSI, a wireless link may suffer from a low signal quality and/or a high interference from other wireless links.

To estimate CSI, the transmitter can send a predefined signal to the receiver. That is, the predefined signal is known to both the transmitter and the receiver. The receiver can then apply various algorithms to perform CSI estimation. At this stage, CSI is known to the receiver only. The transmitter can rely on feedback from the receiver for acquiring CSI knowledge.

Raw CSI feedback, however, may require a large overhead which may degrade the overall system performance and cause a large delay. Thus, the raw CSI feedback is typically avoided.

Alternatively, from CSI, the receiver can extract some important or necessary information for the transmitter operations, such as precoding weights, rank indicator (RI), channel quality indicator (CQI), modulational and coding scheme (MCS), and the like. The extracted information can be much smaller than the raw CSI, and the receiver can only feedback these small pieces of information to the transmitter.

To further reduce the overhead, the receiver can estimate the CSI of the communication link and select a best transmit precoder from a predefined codebook of precoders based on the estimated CSI. Further, the receiver can feed information related to the selected best transmit precoder back to the transmitter, such as PMI from such a codebook. This procedure can consume a great deal of communication resources and place a tremendous strain on a wireless network using modern multiple-input and multiple-output (MIMO) technology.

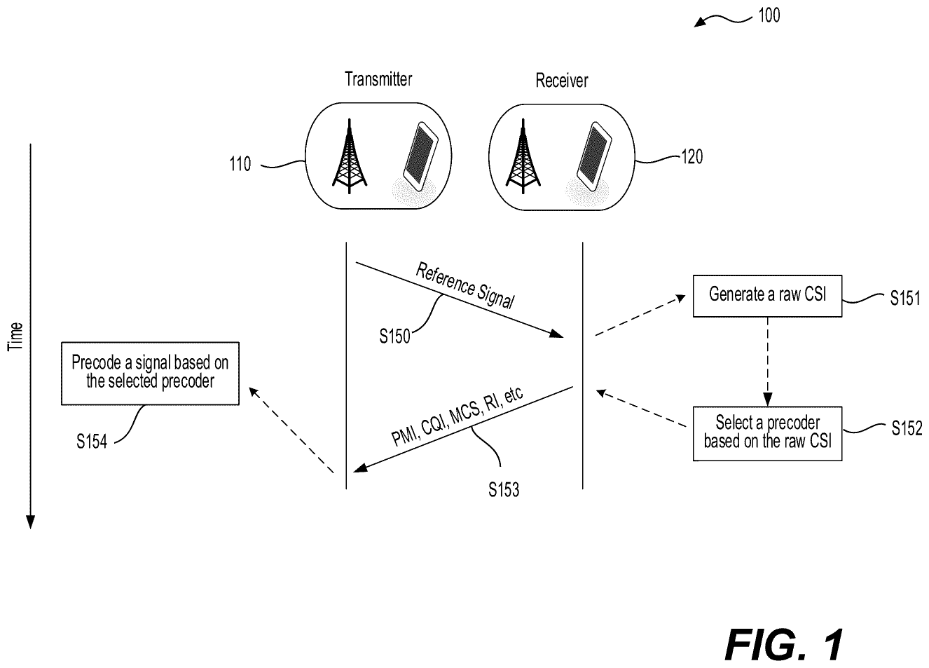

FIG. 1 shows an exemplary procedure 100 of CSI reporting according to embodiments of the disclosure. In the procedure 100, each of a transmitter 110 and a receiver 120 can be a user equipment (UE) or a base station (BS).

At step S150, the transmitter 110 can transmit a reference signal (RS) to the receiver 120. The RS is also known to the receiver 120 before the receiver 120 receives the RS. In an embodiment, the RS can be specifically intended to be used by devices to acquire CSI and thus is referred to as CSI-RS.

At step S151, after receiving the CSI-RS, the receiver 120 can generate a raw CSI by comparing the received CSI-RS with the transmitted CSI-RS that is already known to the receiver 120.

At step S152, the receiver 120 can select a best transmit precoder from a predefined codebook of precoders based on the raw CSI.

At step S153, the receiver 120 can send a PMI of the selected precoder back to the transmitter 110, along with relevant information such as CQI, RI, MCS, and the like.

At step S154, after receiving the PMI and the relevant information, the transmitter 110 can determine transmission parameters and precode a signal based on the selected precoder indicated by the PMI.

It is noted that a choice of the precoders is restricted to the predefined codebook in the procedure 100. However, restricting the choice of the precoders to the predefined codebook can limit the achievable system performance. Different precoder codebooks (e.g., 3GPP NR downlink Type I-Single Panel/Multi-Panel, Type II, eType II, or uplink codebook) have different preset feedback overheads. If the network specifies a preset codebook before the raw CSI is estimated at the receiver, the receiver is not able to further optimize the codebook selection based on tradeoffs between the feedback overhead and the system performance.

Aspects of this disclosure provide methods and embodiments to feedback a compressed version of raw CSI to a transmitter. Based on the compressed CSI, the transmitter is able to optimally compute a precoder for precoding a transmitting signal, and also optimally decide on other transmission parameters such as RI, MCS, and the like. Further, a compression ratio used in compressing the raw CSI can be decided dynamically after the raw CSI has been estimated, in order to allow an optimal tradeoff between the feedback overhead and the system performance.

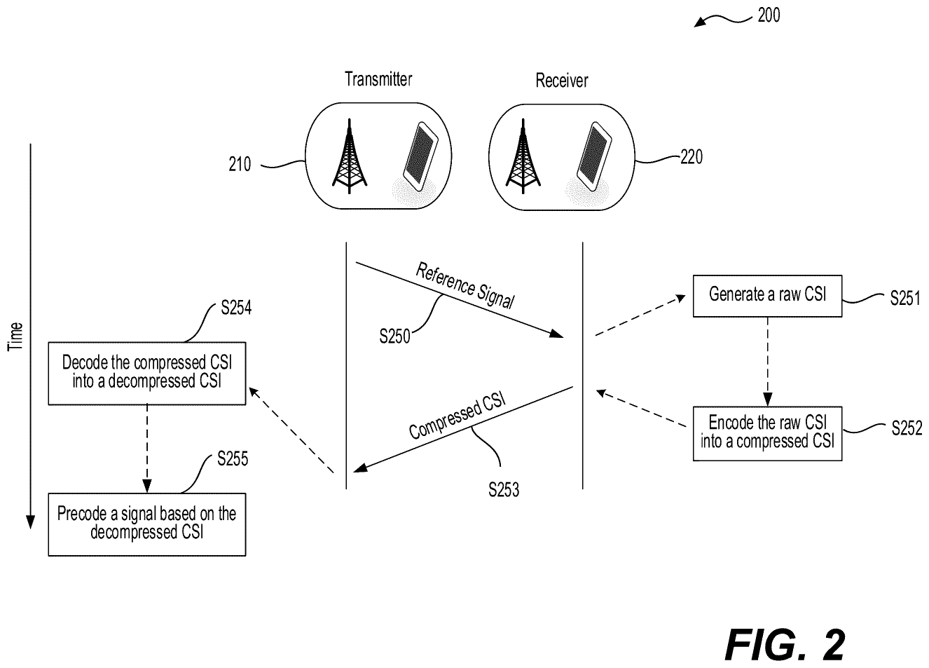

FIG. 2 shows an exemplary procedure 200 of CSI reporting according to embodiments of the disclosure. In the procedure 200, each of a transmitter 210 and a receiver 220 can be a user equipment (UE) or a base station (BS), and steps S250 and S251 are similar to steps S150 and S151 in the procedure 100 of FIG. 1, respectively.

At step S252, the receiver 220 can encode (or compress) the raw CSI into a compressed CSI.

At step S253, the receiver 220 can send the compressed CSI back to the transmitter 210.

At step S254, the transmitter 210 can decode (or decompress) the compressed CSI into a decompressed CSI.

At step S255, the transmitter 210 can determine transmission parameters and precode a signal based on the decompressed CSI.

Although a direct compression of raw CSI is a feasible approach, relying on a single generic CSI encoder-decoder pair, for compression and decompression, puts strict requirements on the capability of the transmitter and receiver and limits compression and decompression performance of the transmitter and receiver since one algorithm is expected to perform well on all possible CSIs.

According to aspects of the disclosure, a pool of encoder-decoder pairs can be used for compressing and decompressing raw CSI, so that a better system performance can be achieved compared to a single generic CSI encoder-decoder pair. Among the pool of encoder-decoder, a CSI classifier algorithm can be used to select a best pair to use. Each encoder-decoder pair can be specialized in compressing and decompressing a corresponding class of data that is classified by the CSI classifier algorithm.

In an embodiment, a set of all possible CSI elements (or vectors) [symbol] can be divided or clustered into multiple (e.g., N) subsets of CIS elements (or vectors) as [symbol] =Uᵢ₌₁^{i=N} [symbol] ᵢ, where [symbol] ᵢ represents a subset of CSI elements (or vectors). Each subset can correspond to a different class of the CSI classifier. Through the division or clustering, the CSI elements with a higher similarity than other CSI elements can be grouped into a same class. A higher similarity indicates a higher redundancy within the same group of CIS elements and thus a higher compression ratio can be achieved.

In an embodiment, for each subset [symbol] ᵢ, a respective pair of compression-decompression algorithms can be trained and used to find an efficient CSI representation. The i^{th} encoder-decoder pair can be optimized to compress the CSI elements in [symbol] ᵢ. In an example, the pair of compression-decompression algorithms can be machine learning based algorithms.

In an embodiment, for a to-be-compressed CSI element h, where h∈ [symbol] , the receiver can classify the to-be-compressed CSI element h using a CSI classifier (or using a CSI algorithm) to find a value of class index i of a class in which the CSI element h is classified. Then, the CSI representation of the class in which the CSI element h is classified can be used for representing a compressed version of the CSI element h.

In an embodiment, the CSI classifier algorithm can include a K-means clustering algorithm, a hierarchical clustering algorithm, a density-based clustering algorithm, a convolutional neural network (CNN) based clustering algorithm, or the like.

In an embodiment, in the K-means clustering algorithm, a plurality of CSI clements can be divided or clustered into a predetermined number K of classes. In an example, the K-means clustering algorithm can work by iteratively assigning cach data point to one of multiple clusters with the nearest mean, and then updating the mean of each cluster based on the data points assigned to the respective cluster.

It is noted that CSI can also be a tensor representation and does not have to be limited to vector representations. Vectors are used for simplicity in this disclosure. In addition, the value of K can be dynamically chosen by the receiver to optimize the tradeoff between the compression and the system performance. A larger K means a smaller average size of each class which indicates higher similarity between elements within the same class. A higher similarity can lead to a higher compression ratio. However, a larger K requires more computation and storage resource to train and restore more different Aₖ.

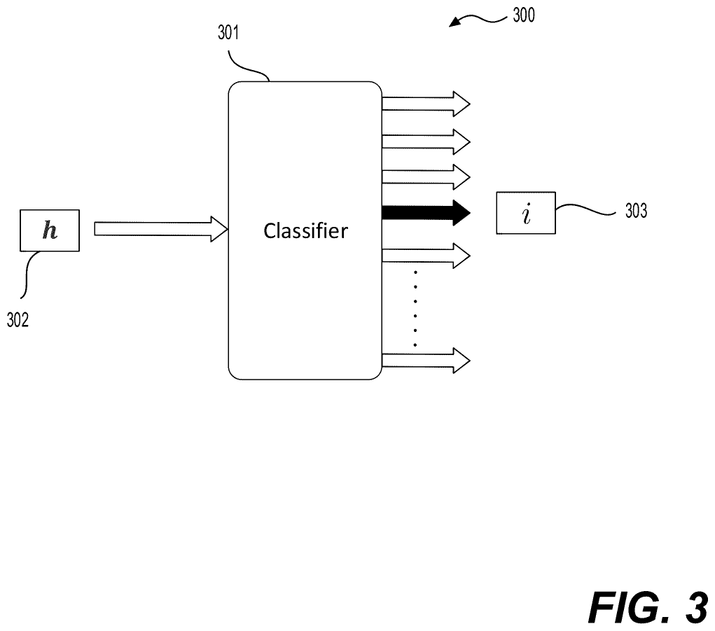

FIG. 3 shows an exemplary procedure 300 of classifying a CSI element 302 according to embodiments of the disclosure. In the procedure 300, the CSI element 302 is input into a classifier 301, which classifies the CSI element 302 into one of multiple classes and assigns a class index i 303 of the one of the multiple classes to the CSI element 302.

In an embodiment, a comprehensive dataset of CSI data, denoted by [symbol] _{D}, can be collected. An integer K can be determined as a number of the classes of the classifier 301. The K-means clustering algorithm can be applied on [symbol] _{D} to obtain a clustered set of [symbol] _{D}_{ₖ}, ∀k∈{1, 2, . . . , K} where [symbol] _{D}=Uₖ₌₁^{k=K} [symbol] _{D}_{ₖ}. Each class of CSI elements [symbol] _{D}_{ₖ} can be used to train a pair of encoder-decoder algorithms Aₖ. The algorithm Aₖ can be specialized in compressing CSI elements in [symbol] _{D}_{ₖ}, but may not be specialized in compressing CSI elements in [symbol] _{D}_{ᵢ}, where i≠k.

In the K-means clustering algorithm, each [symbol] _{D}_{ₖ} can include a plurality of CSI vectors (or elements) and an average of these CSI vectors can be treated as a centroid of [symbol] _{D}_{ₖ}. For each [symbol] _{D}_{ₖ}, a distance between the CSI element 302 and the centroid of the respective [symbol] _{D}_{ₖ} can be calculated, so that a total of K distances can be obtained. The one of the multiple classes assigned to the CSI element 302 has a minimal distance among the K distances.

It is noted that various distance metrics can be used to determine the centroid of [symbol] _{D}_{ₖ} and/or the distance between the CSI element 302 and the centroid of the [symbol] _{D}_{ₖ}. In an example, Euclidean distance can be used in the K-means clustering algorithm.

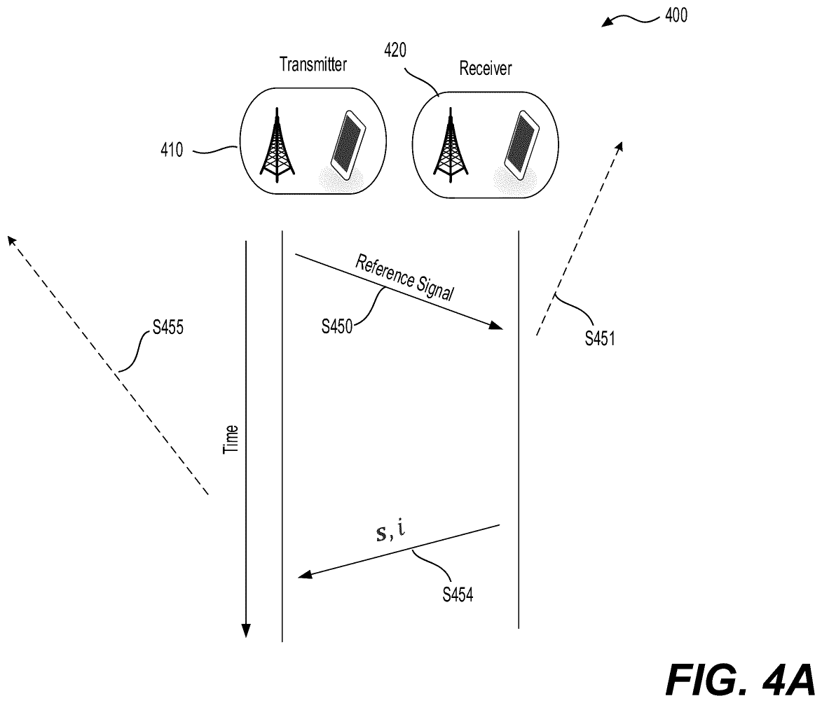

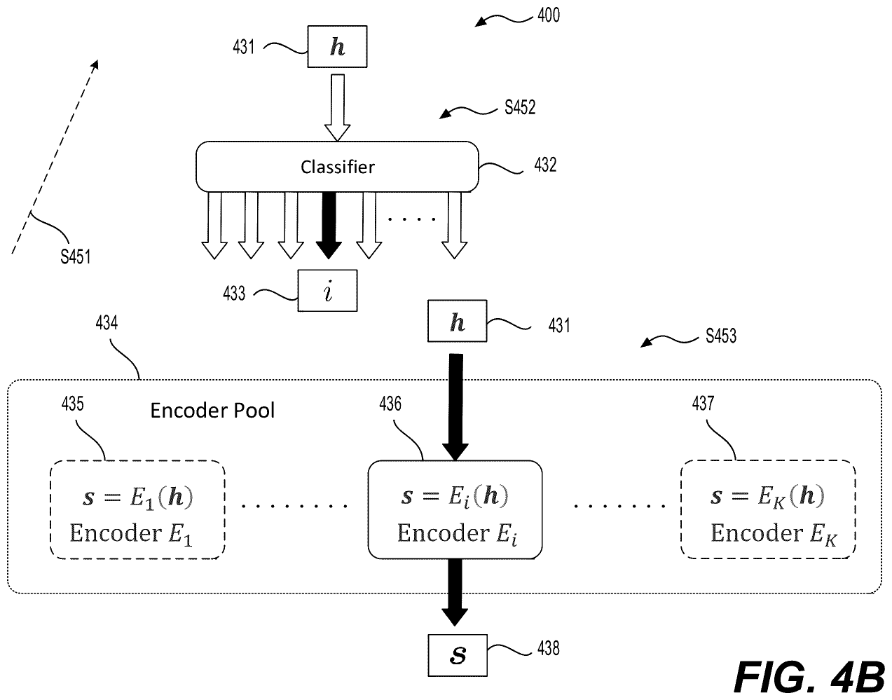

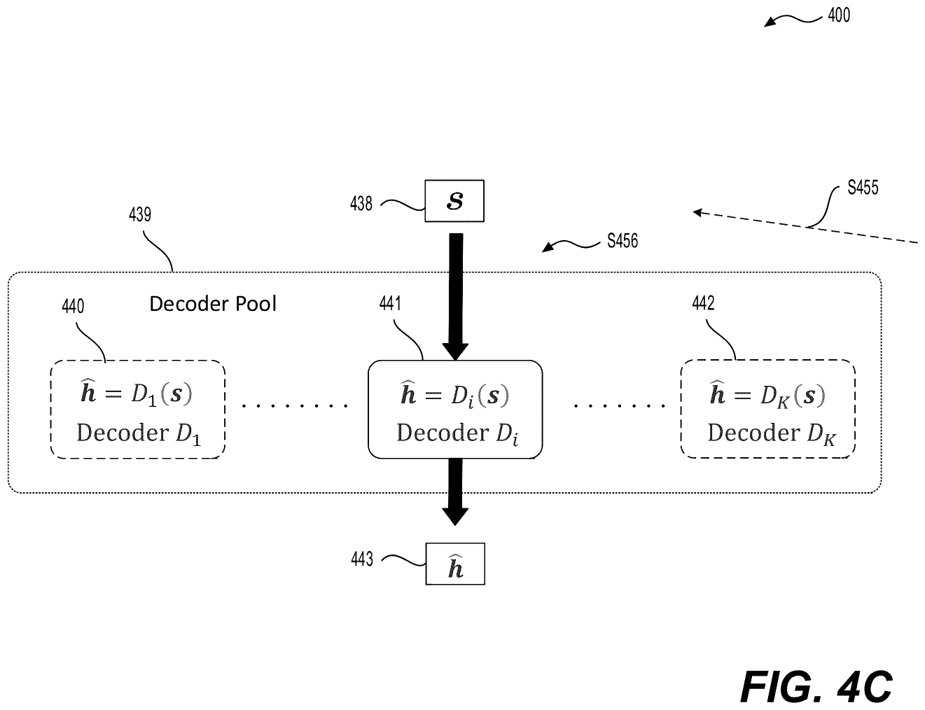

FIG. 4A-4C show an exemplary procedure 400 of CSI reporting according to embodiments of the disclosure. In the procedure 400, each of a transmitter 410 and a receiver 420 can be a user equipment (UE) or a base station (BS). A classifier 432 and an encoder pool 434 including multiple (e.g., K) encoders each corresponding to a CSI class are deployed on the receiver 420. A decoder pool 439 including multiple (e.g., K) decoders each corresponding to a CSI class is deployed on the transmitter 410.

At step S450 (as shown in FIG. 4A), the transmitter 410 can send a reference signal such as CSI-RS to the receiver 420.

At step S451 (as shown in FIG. 4A and 4B), the receiver 420 can obtain a CSI vector h 431 by analyzing the received CSI-RS.

At step S452 (as shown in FIG. 4B), the classifier 432 can determine a class index i 433 for the CSI vector 431.

At step S453 (as shown in FIG. 4B), the receiver 420 can select an encoder Eᵢ 436 from the encoder pool 434 based on the class index i 433. The receiver 420 can use the encoder Eᵢ 436 to encode the CSI vector h 431 to obtain a compressed CSI vector s 438.

At step S454 (as shown in FIG. 4A), the receiver 420 can pair the compressed CSI vector s 438 with the corresponding class index i 433 to form a pair of (s, i) and send the pair to the transmitter 410.

At step S455 (as shown in FIG. 4A and 4C), the transmitter 410 can receive the pair (s, i).

At step S456 (as shown in FIG. 4C), the transmitter 410 can select a decoder Dᵢ 441 from the decoder pool 439 based on the class index i 433. The transmitter 410 can use the decoder Dᵢ 441 to decode the compressed CSI vector s 438 to obtain a decompressed CSI vector ĥ 443 of the original CSI vector h 431. The “hat” symbol over ĥ 443 indicates the decompressed CSI vector ĥ 443 is an estimate of the original CSI vector h 431.

It is noted that the encoder and decoder in an encoder-decoder pair may not be in the same category. For example, the encoder Eᵢ 436 may be a linear operator, while the decoder Dᵢ 441 may be CNN based decoder, although both encoder Eᵢ 436 and decoder Dᵢ 441 are optimized for vectors that belong to the i^{th} class.

Aspects of the disclosure provide a method for raw CSI compression and feedback that can be used either in an uplink (UL) or a downlink (DL). The method including classifying all CSIs into a finite number (e.g., K) of classes by means of a classification algorithm. The method further includes training the finite number (e.g., K) of pairs of specialized encoder-decoder (e.g., compression-decompression) algorithms. Each encoder-decoder pair is targeted for one of the K CSI classes. After estimating the CSI, a receiver can apply a classifier on an obtained CSI clement and find which class this CSI element belongs to. Knowing the CSI class, the receiver can encode (or compress) the CSI element to obtain a representation for CSI with a size smaller than a size of the original CSI element. The receiver can then feedback the compressed CSI element and an index of the CSI class to a transmitter. Knowing the CSI class, the transmitter can select an appropriate decoder to decompress the compressed CSI element. The transmitter finally can obtain an estimate for the original CSI element.

It is noted that the size of the original CSI element is high-level information that may be already known to the transmitter. When the transmitter receives the compressed CSI element, the transmitter can perform a low-complexity decoding of the compressed CSI element (e.g., using machine learning based algorithms or other alternatives) to obtain the estimate of the original CSI.

Benefits of the raw CSI classification, compression, and feedback can include but are not limited to providing a simple and cost-effective raw CSI compression and allowing a flexible choice of the total number K of all the classes of the raw CSI. This technique can be applied to both uplink (UL) and downlink (DL) directions. Classifiers can be used to group CSI into sets of similar statistical behavior. The number of such sets can be chosen flexibly by a system designer to optimize performance.

In addition, various encoder-decoder (compression-decompression) pairs allow for optimizing compression performance for different classes of CSI, while incurring minimal overhead for indicating which pair is used. The compressed CSI can be decompressed (or decoded) at a transmitter by applying various algorithms including but not limited to machine learning based algorithms. Linear compression can allow dividing the compression and feedback into multiple steps, allowing an incremental CSI construction with an improved CSI accuracy and simplifying the decoding at the transmitter. Compressed CSI can help a transmitter optimize transmission parameters. For example, the transmitter can select optimal or close-to-optimal transmission parameters such as precoding matrices, rank selection, MCS selection, and the like.

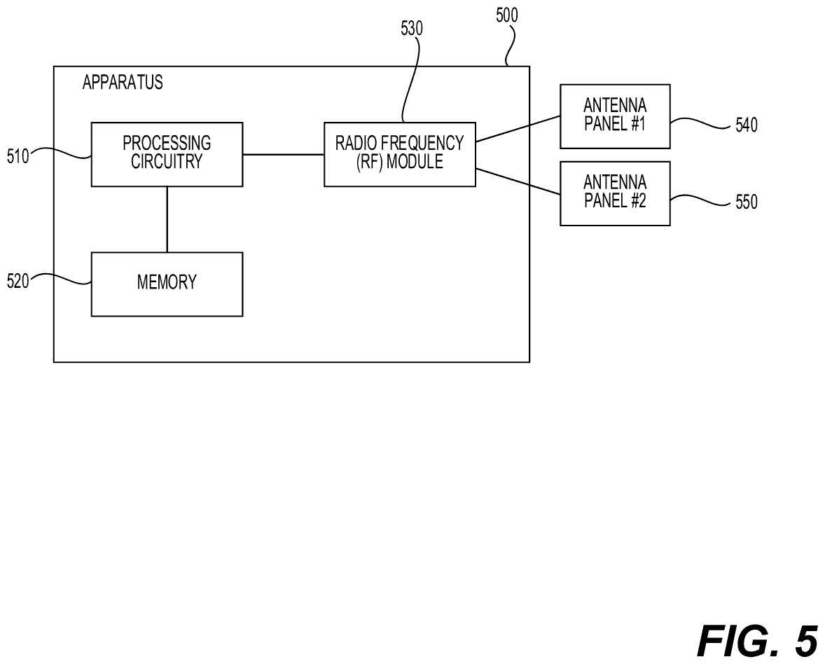

FIG. 5 shows an exemplary apparatus 500 according to embodiments of the disclosure. The apparatus 500 can be configured to perform various functions in accordance with one or more embodiments or examples described herein. Thus, the apparatus 500 can provide means for implementation of techniques, processes, functions, components, systems described herein. For example, the apparatus 500 can be used to implement functions of a UE or a base station (BS) (e.g., gNB) in various embodiments and examples described herein. The apparatus 500 can include a general purpose processor or specially designed circuits to implement various functions, components, or processes described herein in various embodiments. The apparatus 500 can include processing circuitry 510, a memory 520, and a radio frequency (RF) module 530.

In various examples, the processing circuitry 510 can include circuitry configured to perform the functions and processes described herein in combination with software or without software. In various examples, the processing circuitry 510 can be a digital signal processor (DSP), an application specific integrated circuit (ASIC), programmable logic devices (PLDs), field programmable gate arrays (FPGAs), digitally enhanced circuits, or comparable device or a combination thereof.

In some other examples, the processing circuitry 510 can be a central processing unit (CPU) configured to execute program instructions to perform various functions and processes described herein. Accordingly, the memory 520 can be configured to store program instructions. The processing circuitry 510, when executing the program instructions, can perform the functions and processes. The memory 520 can further store other programs or data, such as operating systems, application programs, and the like. The memory 520 can include a read only memory (ROM), a random access memory (RAM), a flash memory, a solid state memory, a hard disk drive, an optical disk drive, and the like.

The RF module 530 receives a processed data signal from the processing circuitry 510 and converts the data signal to beamforming wireless signals that are then transmitted via antenna panels 540 and/or 550, or vice versa. The RF module 530 can include a digital to analog convertor (DAC), an analog to digital converter (ADC), a frequency up convertor, a frequency down converter, filters and amplifiers for reception and transmission operations. The RF module 530 can include multi-antenna circuitry for beamforming operations. For example, the multi-antenna circuitry can include an uplink spatial filter circuit, and a downlink spatial filter circuit for shifting analog signal phases or scaling analog signal amplitudes. Each of the antenna panels 540 and 550 can include one or more antenna arrays.

In an embodiment, part of all the antenna panels 540/550 and part or all functions of the RF module 530 are implemented as one or more TRPs (transmission and reception points), and the remaining functions of the apparatus 500 are implemented as a BS. Accordingly, the TRPs can be co-located with such a BS, or can be deployed away from the BS.

The apparatus 500 can optionally include other components, such as input and output devices, additional or signal processing circuitry, and the like. Accordingly, the apparatus 500 may be capable of performing other additional functions, such as executing application programs, and processing alternative communication protocols.

The processes and functions described herein can be implemented as a computer program which, when executed by one or more processors, can cause the one or more processors to perform the respective processes and functions. The computer program may be stored or distributed on a suitable medium, such as an optical storage medium or a solid-state medium supplied together with, or as part of, other hardware. The computer program may also be distributed in other forms, such as via the Internet or other wired or wireless telecommunication systems. For example, the computer program can be obtained and loaded into an apparatus, including obtaining the computer program through physical medium or distributed system, including, for example, from a server connected to the Internet.

The computer program may be accessible from a computer-readable medium providing program instructions for use by or in connection with a computer or any instruction execution system. The computer readable medium may include any apparatus that stores, communicates, propagates, or transports the computer program for use by or in connection with an instruction execution system, apparatus, or device. The computer-readable medium can be magnetic, optical, electronic, electromagnetic, infrared, or semiconductor system (or apparatus or device) or a propagation medium. The computer-readable medium may include a computer-readable non-transitory storage medium such as a semiconductor or solid-state memory, magnetic tape, a removable computer diskette, a random access memory (RAM), a read-only memory (ROM), a magnetic disk and an optical disk, and the like. The computer-readable non-transitory storage medium can include all types of computer readable medium, including magnetic storage medium, optical storage medium, flash medium, and solid state storage medium.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order and are not meant to be limited to the specific order or hierarchy presented.

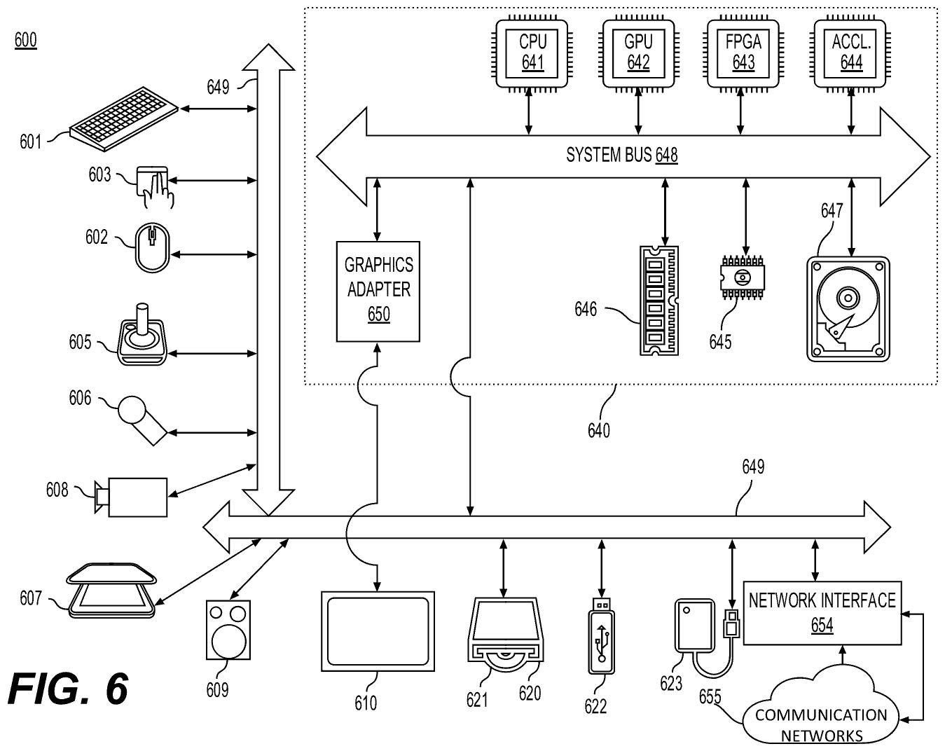

The techniques described above, can be implemented as computer software using computer-readable instructions and physically stored in one or more computer-readable media. For example, FIG. 6 shows a computer system (600) suitable for implementing certain embodiments of the disclosed subject matter.

The computer software can be coded using any suitable machine code or computer language, that may be subject to assembly, compilation, linking, or like mechanisms to create code comprising instructions that can be executed directly, or through interpretation, micro-code execution, and the like, by one or more computer central processing units (CPUs), Graphics Processing Units (GPUs), and the like.

The instructions can be executed on various types of computers or components thereof, including, for example, personal computers, tablet computers, servers, smartphones, gaming devices, internet of things devices, and the like.

The components shown in FIG. 6 for computer system (600) are exemplary in nature and are not intended to suggest any limitation as to the scope of use or functionality of the computer software implementing embodiments of the present disclosure. Neither should the configuration of components be interpreted as having any dependency or requirement relating to any one or combination of components illustrated in the exemplary embodiment of a computer system (600).

Computer system (600) may include certain human interface input devices. Such a human interface input device may be responsive to input by one or more human users through, for example, tactile input (such as: keystrokes, swipes, data glove movements), audio input (such as: voice, clapping), visual input (such as: gestures), olfactory input (not depicted). The human interface devices can also be used to capture certain media not necessarily directly related to conscious input by a human, such as audio (such as: speech, music, ambient sound), images (such as: scanned images, photographic images obtain from a still image camera), video (such as two-dimensional video, three-dimensional video including stereoscopic video).

Input human interface devices may include one or more of (only one of each depicted): keyboard (601), mouse (602), trackpad (603), touch screen (610), data-glove (not shown), joystick (605), microphone (606), scanner (607), and camera (608).

Computer system (600) may also include certain human interface output devices. Such human interface output devices may be stimulating the senses of one or more human users through, for example, tactile output, sound, light, and smell/taste. Such human interface output devices may include tactile output devices (for example tactile feedback by the touch-screen (610), data-glove (not shown), or joystick (605), but there can also be tactile feedback devices that do not serve as input devices), audio output devices (such as: speakers (609), headphones (not depicted)), visual output devices (such as screens (610) to include CRT screens, LCD screens, plasma screens, OLED screens, cach with or without touch-screen input capability, cach with or without tactile feedback capability—some of which may be capable to output two dimensional visual output or more than three dimensional output through means such as stereographic output; virtual-reality glasses (not depicted), holographic displays and smoke tanks (not depicted)), and printers (not depicted). These visual output devices (such as screens (610)) can be connected to a system bus (648) through a graphics adapter (650).

Computer system (600) can also include human accessible storage devices and their associated media such as optical media including CD/DVD ROM/RW (620) with CD/DVD or the like media (621), thumb-drive (622), removable hard drive or solid state drive (623), legacy magnetic media such as tape and floppy disc (not depicted), specialized ROM/ASIC/PLD based devices such as security dongles (not depicted), and the like.

Those skilled in the art should also understand that term “computer readable media” as used in connection with the presently disclosed subject matter does not encompass transmission media, carrier waves, or other transitory signals.

Computer system (600) can also include a network interface (654) to one or more communication networks (655). The one or more communication networks (655) can for example be wireless, wireline, optical. The one or more communication networks (655) can further be local, wide-area, metropolitan, vehicular and industrial, real-time, delay-tolerant, and so on. Examples of the one or more communication networks (655) include local area networks such as Ethernet, wireless LANs, cellular networks to include GSM, 3G, 4G, 5G, LTE and the like, TV wireline or wireless wide area digital networks to include cable TV, satellite TV, and terrestrial broadcast TV, vehicular and industrial to include CANBus, and so forth. Certain networks commonly require external network interface adapters that attached to certain general purpose data ports or peripheral buses (649) (such as, for example USB ports of the computer system (600)); others are commonly integrated into the core of the computer system (600) by attachment to a system bus as described below (for example Ethernet interface into a PC computer system or cellular network interface into a smartphone computer system). Using any of these networks, computer system (600) can communicate with other entities. Such communication can be uni-directional, receive only (for example, broadcast TV), uni-directional send-only (for example CANbus to certain CANbus devices), or bi-directional, for example to other computer systems using local or wide area digital networks. Certain protocols and protocol stacks can be used on each of those networks and network interfaces as described above.

Aforementioned human interface devices, human-accessible storage devices, and network interfaces can be attached to a core (640) of the computer system (600).

The core (640) can include one or more Central Processing Units (CPU) (641), Graphics Processing Units (GPU) (642), specialized programmable processing units in the form of Field Programmable Gate Areas (FPGA) (643), hardware accelerators (644) for certain tasks, graphics adapters (650), and so forth. These devices, along with Read-only memory (ROM) (645), Random-access memory (646), internal mass storage (647) such as internal non-user accessible hard drives, SSDs, and the like, may be connected through the system bus (648). In some computer systems, the system bus (648) can be accessible in the form of one or more physical plugs to enable extensions by additional CPUs, GPU, and the like. The peripheral devices can be attached either directly to the core's system bus (648), or through a peripheral bus (649). In an example, the screen (610) can be connected to the graphics adapter (650). Architectures for a peripheral bus include PCI, USB, and the like.

CPUs (641), GPUs (642), FPGAs (643), and accelerators (644) can execute certain instructions that, in combination, can make up the aforementioned computer code. That computer code can be stored in ROM (645) or RAM (646). Transitional data can be also be stored in RAM (646), whereas permanent data can be stored for example, in the internal mass storage (647). Fast storage and retrieve to any of the memory devices can be enabled through the use of cache memory, that can be closely associated with one or more CPU (641), GPU (642), mass storage (647), ROM (645), RAM (646), and the like.

The computer readable media can have computer code thereon for performing various computer-implemented operations. The media and computer code can be those specially designed and constructed for the purposes of the present disclosure, or they can be of the kind well known and available to those having skill in the computer software arts.

As an example and not by way of limitation, the computer system having architecture (600), and specifically the core (640) can provide functionality as a result of processor(s) (including CPUs, GPUs, FPGA, accelerators, and the like) executing software embodied in one or more tangible, computer-readable media. Such computer-readable media can be media associated with user-accessible mass storage as introduced above, as well as certain storage of the core (640) that are of non-transitory nature, such as core-internal mass storage (647) or ROM (645). The software implementing various embodiments of the present disclosure can be stored in such devices and executed by core (640). A computer-readable medium can include one or more memory devices or chips, according to particular needs. The software can cause the core (640) and specifically the processors therein (including CPU, GPU, FPGA, and the like) to execute particular processes or particular parts of particular processes described herein, including defining data structures stored in RAM (646) and modifying such data structures according to the processes defined by the software. In addition or as an alternative, the computer system can provide functionality as a result of logic hardwired or otherwise embodied in a circuit (for example: accelerator (644)), which can operate in place of or together with software to execute particular processes or particular parts of particular processes described herein. Reference to software can encompass logic, and vice versa, where appropriate. Reference to a computer-readable media can encompass a circuit (such as an integrated circuit (IC)) storing software for execution, a circuit embodying logic for execution, or both, where appropriate. The present disclosure encompasses any suitable combination of hardware and software.

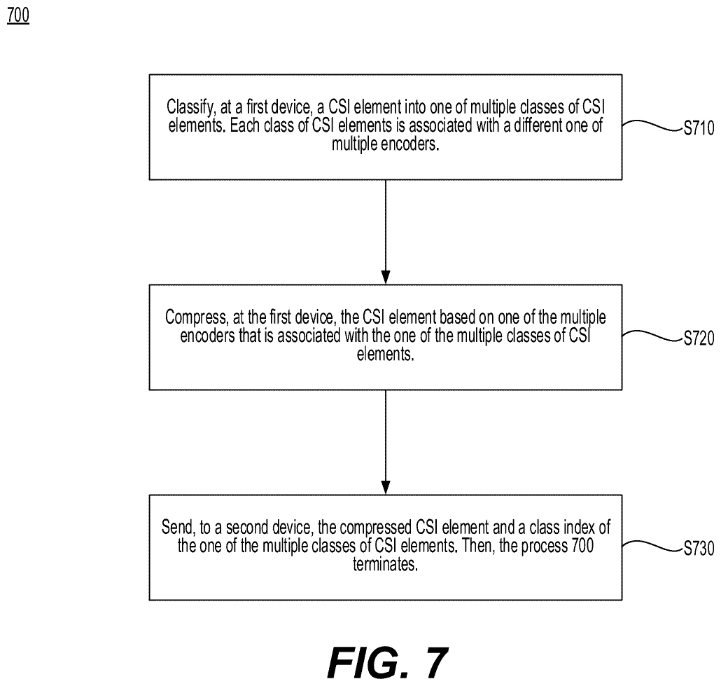

FIG. 7 shows an exemplary process 700 according to embodiments of the disclosure. The process 700 can be executed by the processing circuitry 510 of the apparatus 500 for compressing CSI. The process 700 can also be executed by at least one of the CPU 641, the GPU 642, the FPGA 643, or the accelerator 644 of the computer system 600. The process 700 can be implemented in software instructions, and when the processing circuitry 510 or the at least one of the CPU 641, the GPU 642, the FPGA 643, or the accelerator 644 executes the software instructions, the processing circuitry 510 or the at least one of the CPU 641, the GPU 642, the FPGA 643, or the accelerator 644 performs the process 700.

The process 700 may generally start at step 710, where the process 700 classifies, at a first device, a CSI clement into one of multiple classes of CSI elements. Each class of CSI elements is associated with a different one of multiple encoders. Then, the process 700 proceeds to step S720.

At step S720, the process 700 compresses, at the first device, the CSI element based on one of the multiple encoders that is associated with the one of the multiple classes of CSI elements. Then, the process 700 proceeds to step S730.

At step S730, the process 700 sends, to a second device, the compressed CSI element and a class index of the one of the multiple classes of CSI elements. Then, the process 700 terminates.

In an embodiment, the process 700 clusters, at the first device, a plurality of CSI elements into the multiple classes of CSI elements, and trains a pair of encoder-decoder algorithm for each class of CSI elements.

In an embodiment, the process 700 compresses, at the first device, the CSI clement based on one of the multiple pairs of encoder-decoder algorithms that is associated with the one of the multiple classes of CSI elements.

In an embodiment, the process 700 clusters, at the first device, the plurality of CSI elements into the multiple classes of CSI elements based on a K-mean clustering algorithm.

In an embodiment, a number of the multiple classes of CSI elements is predetermined.

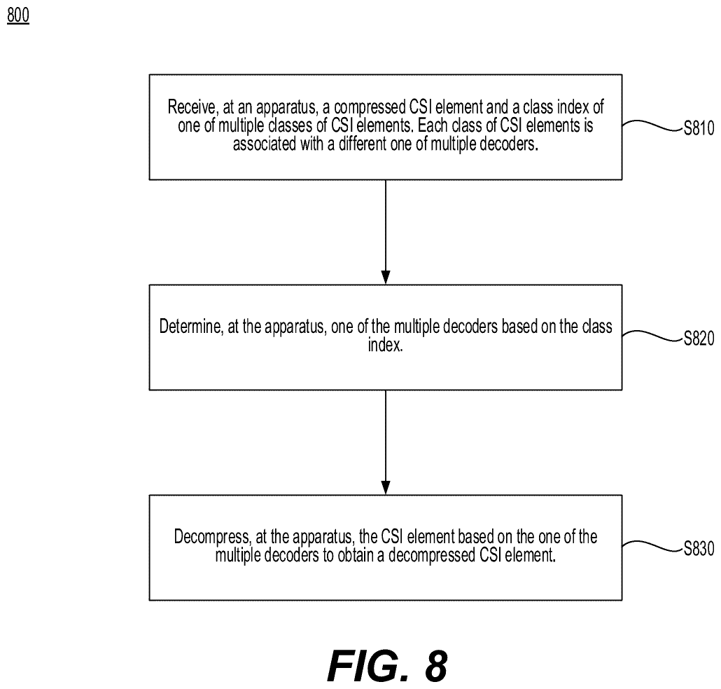

FIG. 8 shows an exemplary process 800 according to embodiments of the disclosure. The process 800 can be executed by the processing circuitry 510 of the apparatus 500 for decompressing CSI. The process 800 can also be executed by at least one of the CPU 641, the GPU 642, the FPGA 643, or the accelerator 644 of the computer system 600. The process 800 can be implemented in software instructions, and when the processing circuitry 510 or the at least one of the CPU 641, the GPU 642, the FPGA 643, or the accelerator 644 executes the software instructions, the processing circuitry 510 or the at least one of the CPU 641, the GPU 642, the FPGA 643, or the accelerator 644 performs the process 800.

The process 800 may generally start at step 810, where the process 800 receives, at an apparatus, a compressed CSI element and a class index of one of multiple classes of CSI elements. Each class of CSI elements is associated with a different one of multiple decoders. Then, the process 800 proceeds to step S820.

At step S820, the process 800 determines, at the apparatus, one of the multiple decoders based on the class index. Then, the process 800 proceeds to step S830.

At step S830, the process 800 decompresses, at the apparatus, the CSI element based on the one of the multiple decoders to obtain a decompressed CSI element.

In an embodiment, each class of CSI elements is associated with a pair of encoder-decoder algorithm.

In an embodiment, the process 800 decompresses, at the apparatus, the CSI element based on one of the multiple pairs of encoder-decoder algorithms that is associated with the one of the multiple classes of CSI elements.

In an embodiment, the multiple classes of CSI elements are clustered from a plurality of CSI elements based on a K-mean clustering algorithm.

In an embodiment, a number of multiple classes of CSI elements is predetermined.

While this disclosure has described several exemplary embodiments, there are alterations, permutations, and various substitute equivalents, which fall within the scope of the disclosure. It will thus be appreciated that those skilled in the art will be able to devise numerous systems and methods which, although not explicitly shown or described herein, embody the principles of the disclosure and are thus within the spirit and scope thereof.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A method of compressing channel state information (CSI), the method comprising:
classifying, at a first device, a CSI element into one of multiple classes of CSI elements, each class of CSI elements being associated with a different one of multiple encoders;
compressing, at the first device, the CSI element based on one of the multiple encoders that is associated with the one of the multiple classes of CSI elements; and
sending, to a second device, the compressed CSI element and a class index of the one of the multiple classes of CSI elements.

2. The method of claim 1, further comprising:
clustering, at the first device, a plurality of CSI elements into the multiple classes of CSI elements; and
training, at the first device, a pair of encoder-decoder algorithm for each class of CSI elements.

3. The method of claim 2, wherein the compression include:
compressing, at the first device, the CSI element based on one of the multiple pairs of encoder-decoder algorithms that is associated with the one of the multiple classes of CSI elements.

4. The method of claim 2, wherein the clustering includes:
clustering, at the first device, the plurality of CSI elements into the multiple classes of CSI elements based on a K-mean clustering algorithm.

5. The method of claim 1, wherein a number of the multiple classes of CSI elements is predetermined.

6. A method of decompressing channel state information (CSI), the method comprising:
receiving, at an apparatus, a compressed CSI element and a class index of one of multiple classes of CSI elements, each class of CSI elements being associated with a different one of multiple decoders;
determining, at the apparatus, one of the multiple decoders based on the class index; and
decompressing, at the apparatus, the CSI element based on the one of the multiple decoders to obtain a decompressed CSI element.

7. The method of claim 6, wherein each class of CSI elements is associated with a pair of encoder-decoder algorithm.

8. The method of claim 7, wherein the decompressing includes:
decompressing, at the apparatus, the CSI element based on one of the multiple pairs of encoder-decoder algorithms that is associated with the one of the multiple classes of CSI elements.

9. The method of claim 6, wherein the multiple classes of CSI elements are clustered from a plurality of CSI elements based on a K-mean clustering algorithm.

10. The method of claim 6, wherein a number of multiple classes of CSI elements is predetermined.

11. An apparatus, comprising:
processing circuitry configured to:
classify a channel state information (CSI) element into one of multiple classes of CSI elements, each class of CSI elements being associated with a different one of multiple encoders;
compress the CSI element based on one of the multiple encoders that is associated with the one of the multiple classes of CSI elements; and
send, to a second apparatus, the compressed CSI element and a class index of the one of the multiple classes of CSI elements.

12. The apparatus of claim 11, wherein the processing circuitry is configured to:
cluster a plurality of CSI elements into the multiple classes of CSI elements; and
train a pair of encoder-decoder algorithm for each class of CSI elements.

13. The apparatus of claim 12, wherein the processing circuitry is configured to:
compress the CSI element based on one of the multiple pairs of encoder-decoder algorithms that is associated with the one of the multiple classes of CSI elements.

14. The apparatus of claim 12, wherein the processing circuitry is configured to:
cluster the plurality of CSI elements into the multiple classes of CSI elements based on a K-mean clustering algorithm.

15. The apparatus of claim 11, wherein a number of the multiple classes of CSI elements is predetermined.

16. An apparatus, comprising:
processing circuitry configured to:
receive a compressed channel state information (CSI) element and a class index of one of multiple classes of CSI elements, each class of CSI elements being associated with a different one of multiple decoders;
determine one of the multiple decoders based on the class index; and
decompress the CSI element based on the one of the multiple decoders to obtain a decompressed CSI element.

17. The apparatus of claim 16, wherein each class of CSI elements is associated with a pair of encoder-decoder algorithm.

18. The apparatus of claim 17, wherein the processing circuitry is configured to:
decompress the CSI element based on one of the multiple pairs of encoder-decoder algorithms that is associated with the one of the multiple classes of CSI elements.

19. The apparatus of claim 16, wherein the multiple classes of CSI elements are clustered from a plurality of CSI elements based on a K-mean clustering algorithm.

20. The apparatus of claim 16. wherein a number of multiple classes of CSI elements is predetermined.
